(19) United States
(12) Patent Application Publication
(10) Pub. No.: US 2025/0104768 A1
(43) Pub. Date: Mar. 27, 2025

(54) A Semiconductor Device

(71) Applicant: Zeno Semiconductor, Inc., Sunnyvale, CA (US)

(72) Inventor: Yuniarto Widjaja, Cupertino, CA (US)

(21) Appl. No.: 18/892,803

(22) Filed: Sep. 23, 2024

Related U.S. Application Data
(60) Provisional application No. 63/584,873, filed on Sep. 23, 2023.
(60) Provisional application No. 63/563,354, filed on Mar. 9, 2024.

(51) Int. Cl. G11C 13/00; H10B 63/00; H10N 70/00

(52) U.S. Cl. CPC G11C 13/0069; H10B 63/30; H10N 70/826; H10N 70/8833; G11C 2013/0078; G11C 2213/79

(57) ABSTRACT

Methods and devices for increasing the on-state drain current of semiconductor devices.

### CROSS-REFERENCE

This application claims the benefit of U.S. Provisional Application No. 63/584,873, filed Sep. 23, 2023 and U.S. Provisional Application No. 63/563,354, filed Mar. 9, 2024, both of which applications are hereby incorporated herein, in their entireties, by reference thereto.

### FIELD OF THE INVENTION

The present invention relates to a semiconductor device having increased on-state current and a non-volatile memory cell comprising a semiconductor device with increased on-state drain current and a resistive change material.

### BACKGROUND OF THE INVENTION

Because PN junctions are created in the source-to-channel and the drain-to-channel of a metal-oxide-semiconductor field-effect transistor (MOSFET), a bipolar junction transistor (BJT) is inherently formed during manufacture of the MOSFET. The inherent BJT is connected in parallel to the MOSFET, where emitter, base, and collector of the BJT are formed from the source, channel, and drain of the MOSFET, respectively. The n-channel MOSFET would have an npn-type BJT and the p-channel MOSFET would have a pnp-type BJT.

In a conventional MOSFET, the intrinsic BJT rarely contributes to the drain current. Currently, the manufacturing process and operation scheme for MOSFETs are designed to nullify the effect of the inherent BJT. A manufacturing process and operation scheme that would utilize the inherent BJT to enhance the MOSFET performance would be desirable.

### SUMMARY OF THE INVENTION

A method to increase on-state drain current of a semiconductor device is disclosed. A non-volatile memory cell comprising a semiconductor device with increased on-state drain current and a resistive change material is disclosed. Methods of operating the non-volatile memory cell are provided.

According to an aspect of the present invention, a method of increasing write current of a non-volatile memory cell includes: providing a non-volatile memory cell including: a semiconductor device comprising a substrate having a first conductivity type selected from p-type conductivity type and n-type conductivity type; a buried layer having a second conductivity type selected from the p-type conductivity type and the n-type conductivity type and being different from the first conductivity type; a body having the first conductivity type; a source region and a drain region each having the second conductivity type and being separated by the body; and a gate positioned in between the source region and the drain region; and a non-volatile memory element connected to one of the source region and the drain region; applying a positive voltage or current to the gate region; applying a positive voltage or current to the drain region; applying zero or a negative voltage or current to the source region; applying zero or a positive voltage or current to the buried layer; and applying a positive voltage or current to the body; thereby increasing current flow from the drain region to the source region, thereby increasing write current of the non-volatile memory cell.

In at least one embodiment, the applying a positive voltage to the body lowers a threshold voltage of the semiconductor device.

In at least one embodiment, the applying a positive voltage or current to the body turns on an intrinsic lateral bipolar transistor formed by the source region, the body and the drain region.

In at least one embodiment, the intrinsic lateral bipolar transistor contributes to higher current flow from the drain region to the source region.

In at least one embodiment, the applying zero or a positive voltage to the buried layer comprises applying the positive voltage to the buried layer to provide additional current flow from the buried layer to the source region.

In at least one embodiment, the applying zero or a negative voltage or current to the source region comprises applying the negative voltage or current to the source region, so that the applying the positive voltage to the buried layer is a lower positive voltage than a positive voltage required to be applied to the buried layer to achieve increased on-state drain current when zero voltage or current is applied to the source region.

According to an aspect of the present invention, a non-volatile memory cell configured to function with increased on-state drain current while in write operation is provided to include: a substrate having a first conductivity type selected from p-type conductivity type and n-type conductivity type; a buried layer having a second conductivity type selected from the p-type conductivity type and the n-type conductivity type and being different from the first conductivity type; a body having the first conductivity type; a source region and a drain region each having the second conductivity type and being separated by the body; a gate positioned in between the source region and the drain region; and a non-volatile memory element connected to one of the source region and the drain region, wherein application of a positive voltage or current to the gate region, a positive voltage or current to the drain region, zero or a negative voltage or current to the source region, zero or a positive voltage or current to the buried layer, and a positive voltage or current to the body increases current flow from the drain region to the source region.

In at least one embodiment, the application of a positive voltage or current to the body turns on an intrinsic lateral bipolar transistor formed by the source region, the body and the drain region.

In at least one embodiment, the intrinsic lateral bipolar transistor contributes to higher current flow from the drain region to the source region.

In at least one embodiment, the application of zero or a positive voltage to the buried layer comprises applying the positive voltage to the buried layer to provide additional current flow from the buried layer to the source region.

In at least one embodiment, the application of zero or a negative voltage or current to the source region comprises applying the negative voltage or current to the source region, so that the application of the positive voltage to the buried layer is a lower positive voltage than a positive voltage required to be applied to the buried layer to achieve increased on-state drain current when zero voltage or current is applied to the source region.

In at least one embodiment, the semiconductor device further includes: a body contact having the first conductivity type; wherein the positive voltage or current to the body is applied through the body contact.

In at least one embodiment, the body contact is more highly doped than the body.

In at least one embodiment, the semiconductor device further includes: a buried layer contact region having the second conductivity type; and a buried layer contact body having the second conductivity type and interconnecting the buried layer contact region and the buried layer; wherein the application of zero or a positive voltage or current to the buried layer is applied through the buried layer contact region and the buried layer contact body.

In at least one embodiment, the buried layer contact region is more highly doped than the buried layer contact body

According to an aspect of the present invention, a method of increasing write current of a non-volatile memory cell includes: providing the non-volatile memory cell including: a semiconductor device including a substrate having a first conductivity type selected from p-type conductivity type and n-type conductivity type; a buried layer having a second conductivity type selected from the p-type conductivity type and the n-type conductivity type and being different from the first conductivity type; a body having the first conductivity type; a source region and a drain region each having the second conductivity type and being separated by the body; and a gate positioned in between the source region and the drain region; and a non-volatile memory element connected to one of the source region and the drain region; applying a positive voltage or current to the gate region; applying a positive voltage or current to the drain region; applying zero or a negative voltage or current to the source region; applying zero voltage or current to the substrate; and applying a positive voltage or current to the buried layer; wherein the positive voltage or current applied by the applying a positive voltage or current to the buried layer is sufficiently high to cause an ionization impact process forming a base current of an inherent lateral bipolar junction transistor (BJT); wherein the positive voltage or current applied by the applying a positive voltage or current to the gate region and/or drain region is sufficiently high to elevate a potential of the body to a level to turn on an inherent vertical bipolar junction transistor (BJT); wherein the on-state drain current of the semiconductor device is a sum of MOS transistor (formed by the source region, the gate region, the drain region and the body) current and current through the lateral BJT; and wherein total current flow into the source region is a sum of the MOS transistor current, the current through the lateral BJT and current through the vertical BJT.

In at least one embodiment, an off-state current of the semiconductor device is the same as when voltage or current applied to the buried layer is zero.

In at least one embodiment, the applying a positive voltage or current to the buried layer comprises applying about three volts to the buried layer.

In at least one embodiment, the applying zero or a negative voltage or current to the source region comprises applying the negative voltage or current to the source region, so that the application of the positive voltage to the buried layer is a lower positive voltage than a positive voltage required to be applied to the buried layer to achieve increased on-state drain current when zero voltage or current is applied to the source region.

In at least one embodiment, the negative voltage or current applied to the source region is-0.2 V and the positive voltage applied to the buried layer is +2.8 V.

These and other advantages and features of the invention will become apparent to those persons skilled in the art upon reading the details of the embodiments as more fully described below.

### BRIEF DESCRIPTION OF THE DRAWINGS

FIG. 1A illustrates a cross-sectional view of a semiconductor device having an increased current flow, according to an embodiment of the present invention.

FIG. 1B illustrates a cross-sectional view of a semiconductor device having an increased current flow, according to an embodiment of the present invention.

FIG. 2 illustrates a cross-sectional view of a plurality of semiconductor devices shown in FIGS. 1A and 1B.

FIG. 3A illustrates an equivalent circuit representation of the semiconductor devices shown in FIGS. 1A and 1B.

FIG. 3B illustrates a source current versus gate voltage relationship of the semiconductor device shown in FIGS. 1A and 1B.

FIGS. 4A and 4B illustrate a cross-sectional view of a semiconductor memory cell having an increased current flow.

FIG. 5 illustrates a memory array comprising memory cells shown in FIG. 4A or 4B.

FIGS. 6A and 6B illustrate cross-sectional views of the semiconductor memory array shown in FIG. 5A, along the column direction.

FIG. 7 schematically illustrates waveforms of signals applied to the WL, BL, and BW terminals during a write operation of a memory cell, according to an embodiment of the present invention.

FIG. 8 schematically illustrates waveforms of signals applied to the WL, BL, and BW terminals during a write operation of a memory cell, according to an embodiment of the present invention.

FIG. 9 illustrates a semiconductor device according to an embodiment of the present invention.

FIG. 10 illustrates an array of semiconductor devices having the same body region, according to an embodiment of the present invention.

FIG. 11 illustrates an equivalent circuit representation of the semiconductor device illustrated in FIG. 9.

FIG. 12 illustrates a non-volatile memory cell comprising a semiconductor device functioning as a select device for a non-volatile memory element according to an embodiment of the present invention.

FIG. 13. shows a cross-sectional view of a memory array 402 including semiconductor devices along with non-volatile memory elements, according to an embodiment of the present invention.

### DETAILED DESCRIPTION OF THE INVENTION

Before the present memory cells, memory arrays and devices are described, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “an”, and “the” include plural referents unless the context clearly dictates otherwise. Thus, for example, reference to “a cell” includes a plurality of such cells and reference to “the body” includes reference to one or more bodies and equivalents thereof known to those skilled in the art, and so forth.

The publications discussed herein are provided solely for their disclosure prior to the filing date of the present application. The dates of publication provided may be different from the actual publication dates which may need to be independently confirmed.

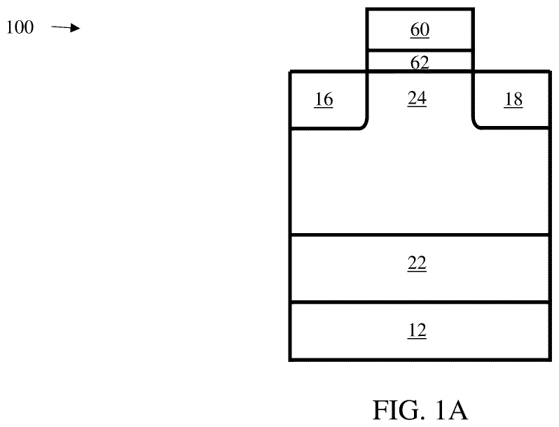

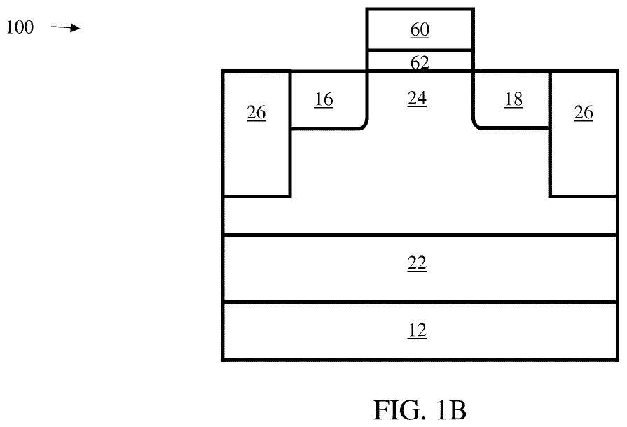

FIG. 1A illustrates a semiconductor device 100, which includes a substrate 12 of a first conductivity type such as p-type, for example. Substrate 12 is typically made of silicon, but may also comprise, for example, germanium, silicon germanium, gallium arsenide, and/or other semiconductor materials. In some embodiments of the invention, substrate 12 can be the bulk material of the semiconductor wafer.

Semiconductor device 100 also includes a buried layer 22 of a second conductivity type, such as n-type, for example; a body 24 of the first conductivity type, such as p-type, for example; and source/drain regions 16 and 18 of the second conductivity type, such as n-type, for example. Buried layer 22 may be formed by an ion implantation process on the material of substrate 12. Alternatively, buried layer 22 can be grown epitaxially on top of substrate 12 or formed through a solid state diffusion process. Body 24 may be the portion of the original substrate 12 above buried layer 22 if buried layer 22 is implanted. Alternatively, body 24 may be epitaxially grown on top of the buried layer 22 through a solid state diffusion process.

A source 16 and drain 18 having a second conductivity type, such as n-type, for example, are provided in body 24, so as to bound a portion of the top of the body 24. Source 16 and drain 18 may be formed by an implantation process on the material making up substrate 12, according to any implantation process known and typically used in the art. Alternatively, a solid state diffusion or a selective epitaxial growth process could be used to form source 16 and drain 18.

A gate 60 is positioned in between the source 16 and the drain 18, above body 24. The gate 60 is insulated from the body 24 by an insulating layer 62. Insulating layer 62 may be made of silicon oxide and/or other dielectric materials, including high-K dielectric materials, such as, but not limited to, tantalum peroxide, titanium oxide, zirconium oxide, hafnium oxide, and/or aluminum oxide. The gate 60 may be made of, for example, polysilicon material or metal gate electrode, such as tungsten, tantalum, titanium and their nitrides

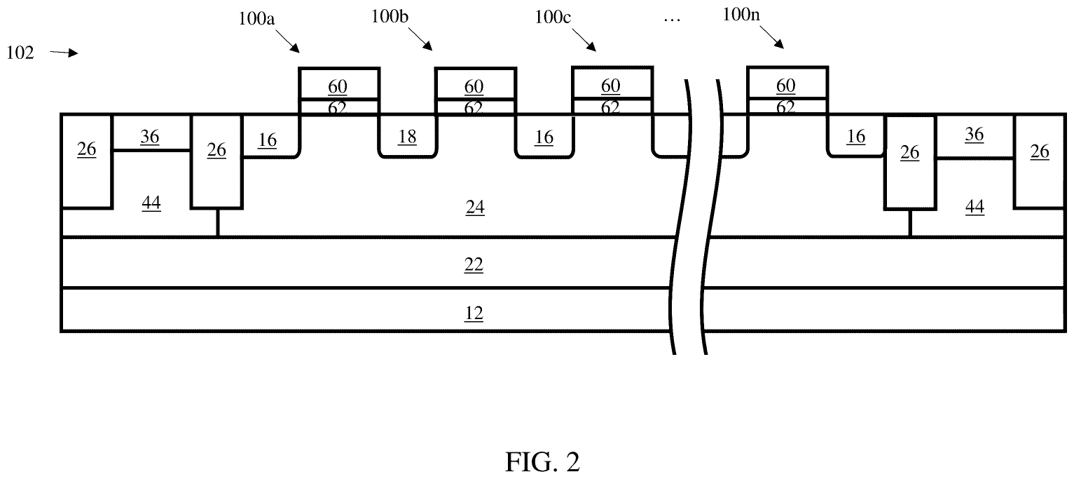

Semiconductor device 100 may also be bounded by insulating layers 26, for example as shown in FIG. 1B. Insulating layers 26 (like, for example, shallow trench isolation (STI)), may be made of silicon oxide, for example, though other insulating materials may be used. The bottom of insulating layer 26 resides above the buried layer 22 allowing buried layer 22 to be continuous as shown in FIG. 1B. It is not necessary to have insulating layers 26 to bound all semiconductor device 100. Therefore, an array of semiconductor devices can be formed by a combination of semiconductor devices 100 shown in FIG. 1A and FIG. 1B. FIG. 2 illustrates an array 102 comprising a plurality of semiconductor devices 100, which are labeled as 100a, 100b, . . . , 100n. Also shown in FIG. 2 is buried layer contact region 36 and buried layer contact body 44, both having a second conductivity type. Buried layer contact region 36 is typically more highly doped compared to the buried layer contact body 44 to lower the contact resistance. Buried layer contact region 36 may be used to apply voltage and/or current bias to the buried layer 22.

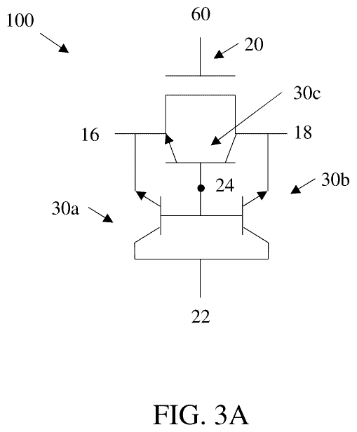

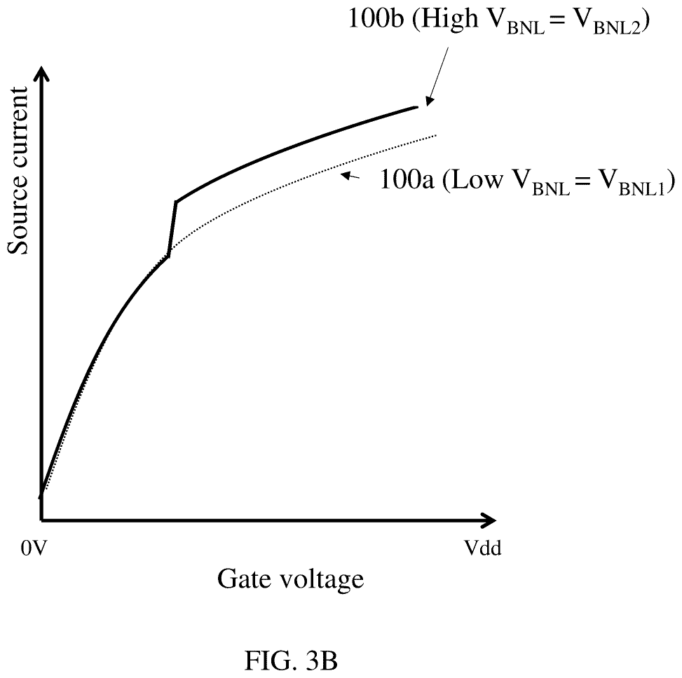

FIG. 3A illustrates an equivalent circuit representation of semiconductor device 100 according to an embodiment of the present invention. Inherent in semiconductor device 100 are metal-oxide-semiconductor (MOS) transistor 20, formed by source 16, gate 60, drain 18, and body 24, and vertical BJTs 30a and 30b, formed by buried layer 22, body 24, and source 16 or drain 18, respectively. Also inherent in semiconductor device 100 is lateral BJT 30c, formed by source 16, body 24, and drain 18.

Application of a positive voltage or current bias to the buried well region 22 may increase the current flow (from the drain region 18 to the source region 16 and from the buried well region 22 to the source region 16) when semiconductor device 100 is in conducting mode. When semiconductor device 100 is in conducting mode, a positive voltage is applied to the gate region 60, a positive voltage is applied to the drain region 18, about zero voltage is applied to the source region 16, and about zero voltage is applied to the substrate region 12. When a positive voltage is applied to the gate 60 and/or drain 18, the potential of the body region 24 can be elevated to be greater than a potential required to turn-on vertical BJT 30a and/or 30b through capacitive coupling. When the vertical BJT 30a is turned on, electrons from source 16 (emitter) flow to the buried layer 22 (collector) of the vertical BJT 30a. The positive voltage applied to the buried well region 22 is sufficiently high to cause impact ionization process, and electron hole pairs are generated near a junction between the body 24 and the buried layer 22. The generated electrons are collected by the positively biased buried layer 22, while the generated holes flow into the body 24. These generated holes act as a base current of the lateral BJT 30c, which turns on the lateral BJT 30c. As a result, the on-state drain current becomes the sum of MOS transistor 20 current and lateral BJT 30c current, while the total current flow into the source region 16 becomes the sum of MOS transistor 20 current, lateral BJT 30c current, and vertical BJT 30a current. As shown in the source 16 current versus gate 60 voltage characteristics of FIG. 3B, the on-state source 16 (and drain 18) current 100b is boosted when a sufficiently high voltage is applied to the buried layer 22 (high V_{BNL}=V_{BNL2}) compared to the on-state currents 100a when a low buried well region (low V_{BNL}=V_{BNL1}) is applied. If desired, the on-state source and drain current can be further boosted by increasing the voltage applied to the buried layer 22. However, the off-state drain current can be the same as the off-state drain current with the buried layer 22 biased at zero, because the body 24 potential at the gate voltage of zero becomes smaller than the threshold voltage for turning on the vertical BJT 30a. Therefore, at a positive bias high V_{BNL2}, semiconductor device 100 functions as a transistor with increased on-state drain current, but with no change in the off-state drain current.

When the voltage applied to the buried layer 22 is less than a voltage to cause an impact ionization process near the junction between buried layer 22 and the body 24 (low V_{BNL1}), no lateral BJT 30c action takes place at any body 24 potentials.

In one particular non-limiting embodiment, high V_{BNL} (V_{BNL2}) is about +3.0 volts, and low V_{BNL} (V_{BNL1}) is a positive voltage lower than +3.0 volts. However, these voltage levels may vary. These voltage levels may depend for example on the doping profile and the depth of the buried layer region 22.

In another non-limiting embodiment, a negative voltage may be applied to the source region 16. As a result, a lower positive voltage V_{BNL2} can be applied, while still maintaining the potential difference between the buried layer 22 (collector) and the source region 16 (emitter) that will result in increased on-state drain current. For example, a negative voltage-0.2 volts may be applied to the source region 16, which will then lower the V_{BNL2} to +2.8 volts.

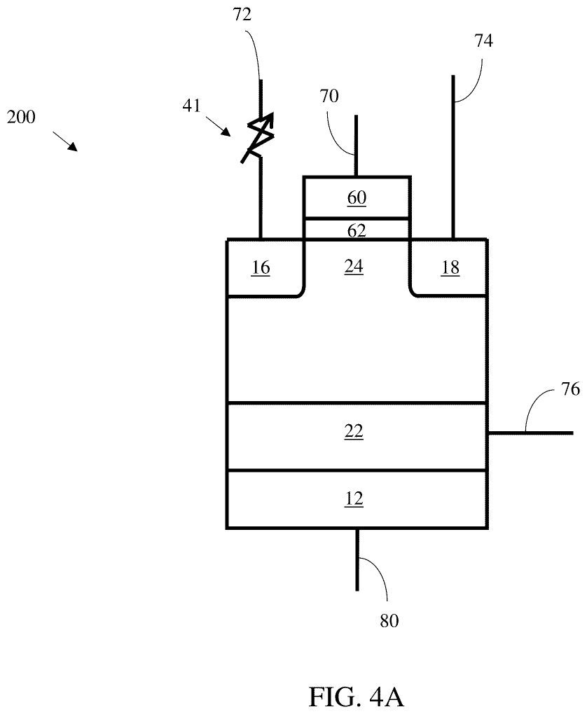

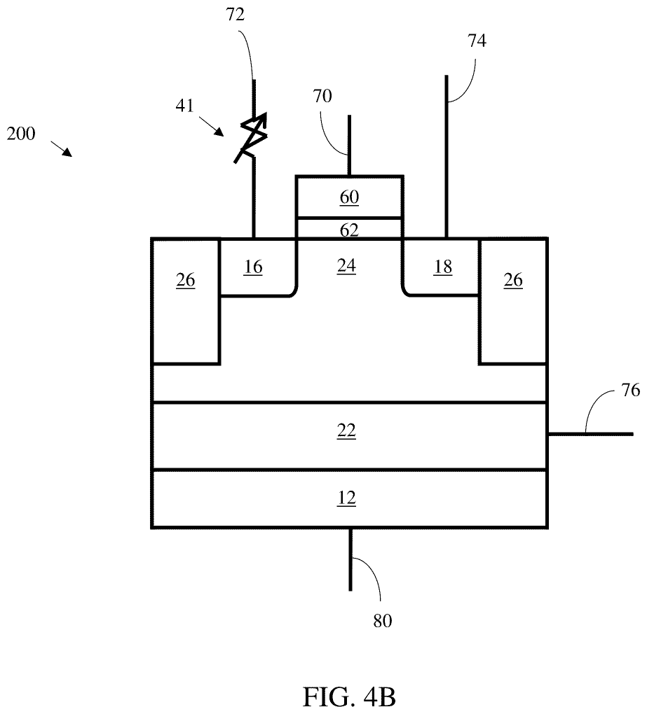

FIG. 4A illustrates a non-volatile memory cell 200 according to an embodiment of the present invention. Memory cell 200 includes a substrate 12 of a first conductivity type such as p-type, for example. Substrate 12 is typically made of silicon, but may also comprise, for example, germanium, silicon germanium, gallium arsenide, and/or other semiconductor materials. In some embodiments of the invention, substrate 12 can be the bulk material of the semiconductor wafer.

Memory cell 200 also includes a buried layer 22 of a second conductivity type, such as n-type, for example; a body 24 of the first conductivity type, such as p-type, for example; and source/drain regions 16 and 18 of the second conductivity type, such as n-type, for example. Buried layer 22 may be formed by an ion implantation process on the material of substrate 12. Alternatively, buried layer 22 can be grown epitaxially on top of substrate 12 or formed through a solid state diffusion process. Body 24 may be the portion of the original substrate 12 above buried layer 22 if buried layer 22 is implanted. Alternatively, body 24 may be epitaxially grown on top of the buried layer 22 through a solid state diffusion process.

A source 16 and drain 18 having a second conductivity type, such as n-type, for example, are provided in body 24, so as to bound a portion of the top of the body 24. Source 16 and drain 18 may be formed by an implantation process on the material making up substrate 12, according to any implantation process known and typically used in the art. Alternatively, a solid state diffusion or a selective epitaxial growth process could be used to form source 16 and drain 18.

A gate 60 is positioned in between the source 16 and the drain 18, above body 24. The gate 60 is insulated from the body 24 by an insulating layer 62. Insulating layer 62 may be made of silicon oxide and/or other dielectric materials, including high-K dielectric materials, such as, but not limited to, tantalum peroxide, titanium oxide, zirconium oxide, hafnium oxide, and/or aluminum oxide. The gate 60 may be made of, for example, polysilicon material or metal gate electrode, such as tungsten, tantalum, titanium and their nitrides.

Memory cell 200 may also be bounded by insulating layers 26, for example as shown in FIG. 4B. Insulating layers 26 (like, for example, shallow trench isolation (STI)), may be made of silicon oxide, for example, though other insulating materials may be used. The bottom of insulating layer 26 resides above the buried layer 22 allowing buried layer 22 to be continuous as shown in FIG. 4B.

Memory cell 200 further comprises resistive change element 41. In this example, non-volatile memory element 41 is a resistive change element and is shown as a variable resistor. Resistive change element 41 may be formed from phase change memory material such as a chalcogenide or conductive bridging memory or metal oxide memory, and may take the form of metal-insulator-metal structure, in which transition metal oxide or perovskite metal oxide is used in conjunction with any reasonably good conductors, for example as described in “Overview of Phase-Change Chalcogenide Non-volatile Memory Technology”, S. Hudgens and b. Johnson, MRS Bulletin, vol. 29, issue 11, November 2004, p. 829-832, “Phase Change Memory”, Wong, H.-S. P. et al., Proceedings of the IEEE, vol. 98, no. 12, December 2010, pp. 2201-2227, “Nanoionics-based resistive switching memories”, R. Waser and M. Aono, Nature Materials, vol. 6, November 2007, pp. 833-840, and “Metal-Oxide RRAM”, Wong, H.-S. P. et. al., Proceedings of the IEEE, vol. 100, no. 6, June 2012, pp. 1951-1970, “Non-volatile RRAM embedded into 22FFL FinFET technology”, Golonzka, O. et al., 2019 Symposium on VLSI Technology, all of which are hereby incorporated herein, in their entireties, by reference thereto. Non-volatile memory element 41 may also comprise magnetoresistive change materials, ferroelectric, and/or ferromagnetic materials, for example as described in “MRAM as Embedded Non-Volatile Memory Solution for 22FFL FinFET Technology”, Golonzka, O. et al., 2018 IEEE International Electron Devices Meeting (IEDM), which is hereby incorporated herein, in its entirety, by reference thereto.

The resistive change element 41 is connected to the source or drain region 16 or 18 of the memory cell 200 having a buried layer 22, typically through a conductive element (for example via and metal used to form semiconductor circuits). FIGS. 4A and 4B illustrate embodiments where the resistive change element 41 is connected to the source region 16.

The semiconductor memory cell 200 further includes a word line (WL) terminal 70 electrically connected to gate 60, a bit line (BL) terminal 74 electrically connected to drain region 18, a source line (SL) terminal 72 electrically connected to non-volatile memory element 41, which is subsequently connected to the source region 16, a buried well (BW) terminal 76 electrically connected to buried layer region 22, and a substrate terminal 80 electrically connected to substrate 12. Alternatively, the BL terminal 74 may be electrically connected to non-volatile memory element 41 and subsequently to the drain region 18 and SL terminal 72 may be electrically connected to the source region 16.

The state of the memory cell 200 is determined by the resistivity of the resistive change element 41. The resistive change element 41 is written (from a low resistivity state to a high resistivity state and vice versa) by flowing an electrical current through the resistive change element 41. In the case of phase change materials, this involves the change of the crystallinity of the chalcogenide materials from crystalline state to amorphous state, while in metal oxide materials, this typically involves the annihilation of conductive filaments.

As a result, it is typically desired to have a higher current flow through the memory cell 200 to enhance the write operation. The higher current flow can be achieved by applying a positive bias to the buried layer region 22. The increased efficiency of the write operations may be used to increase the operating speed, or to lower the voltage applied for the write operations, reducing the operating power of the non-volatile memory cell 200 and enhance the reliability of the non-volatile memory cell 200.

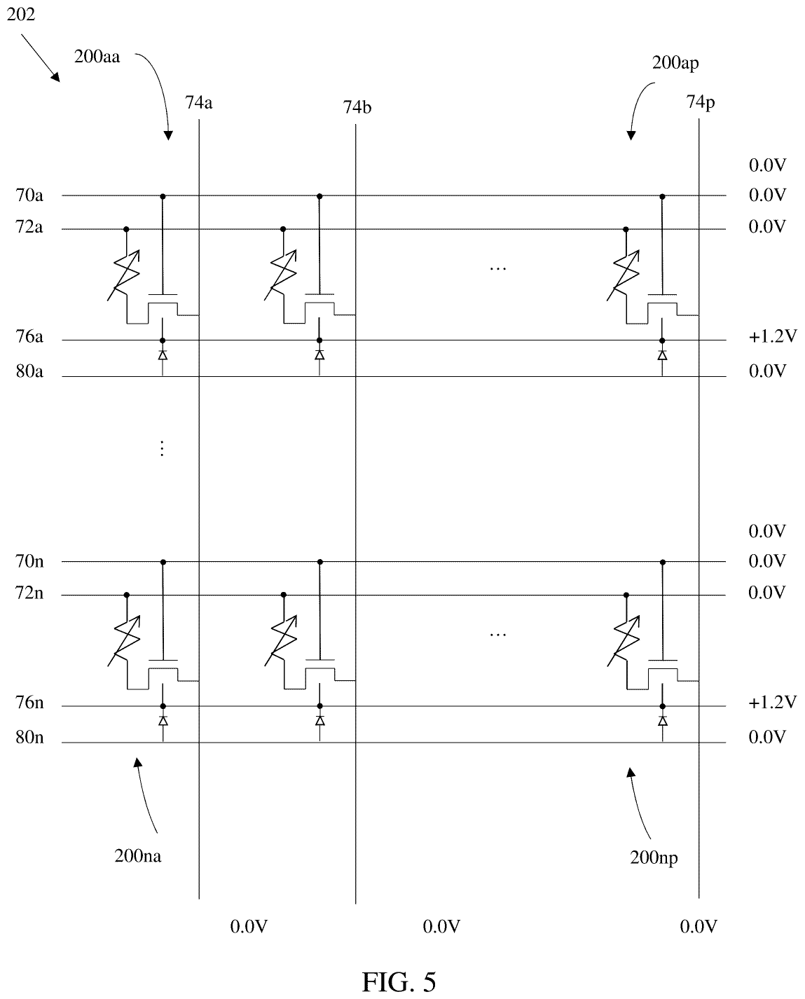

FIG. 5 illustrates a memory array 202 comprising a plurality of memory cells 200 arranged in rows (row a to row n) and columns (column a to column p). FIG. 5 shows four exemplary instances of memory cells 200 being labeled as 200aa, 200na, 200ap, and 200np. The first subscript refers to the row where the memory cell is located and the second subscript refers to the column where the memory cell is located.

Also present in FIG. 5 are WL terminals 70a to 70n, SL terminals 72a to 72n, BL terminals 74a to 74p, BW terminals 76a to 76n, and SUB terminals 80a to 80n. Each of the WL, SL, and BW terminals are shown associated with a single row of memory cells 200 and each of the BL terminals are shown associated with a single column of memory cells 200. Persons of ordinary skill in the art will appreciate that many other organizations and layouts of memory array 202 are possible, for example, only one common SUB terminal 80 is present throughout a segment of the memory array 202 or throughout the entire memory array 202. Similarly, other terminals may be segmented or buffered, while control circuits such as word decoders, column decoders, segmentation devices, sense amplifiers, write amplifiers, etc., may be arrayed around array 202 or inserted between sub-arrays of array 202. Thus the exemplary embodiments, features, design options, etc., described are not limiting in any way.

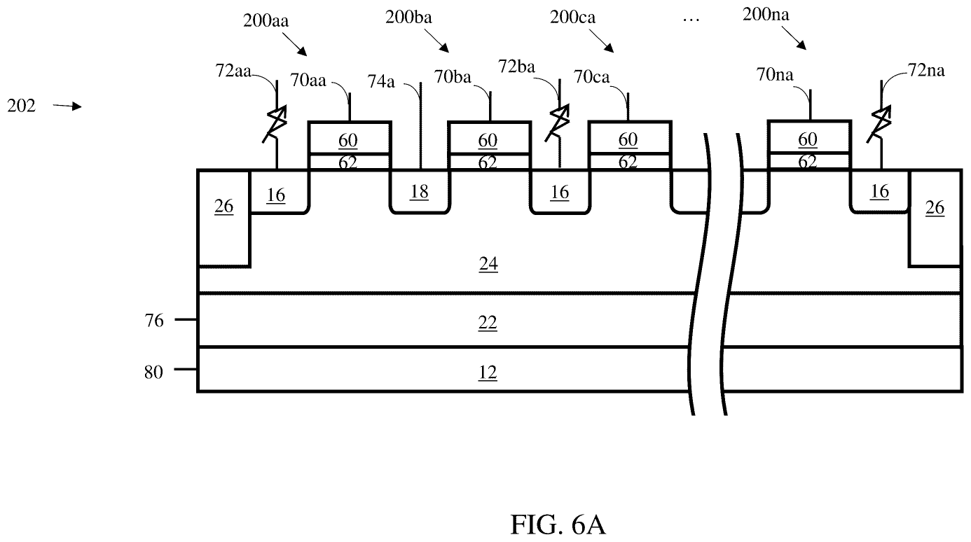

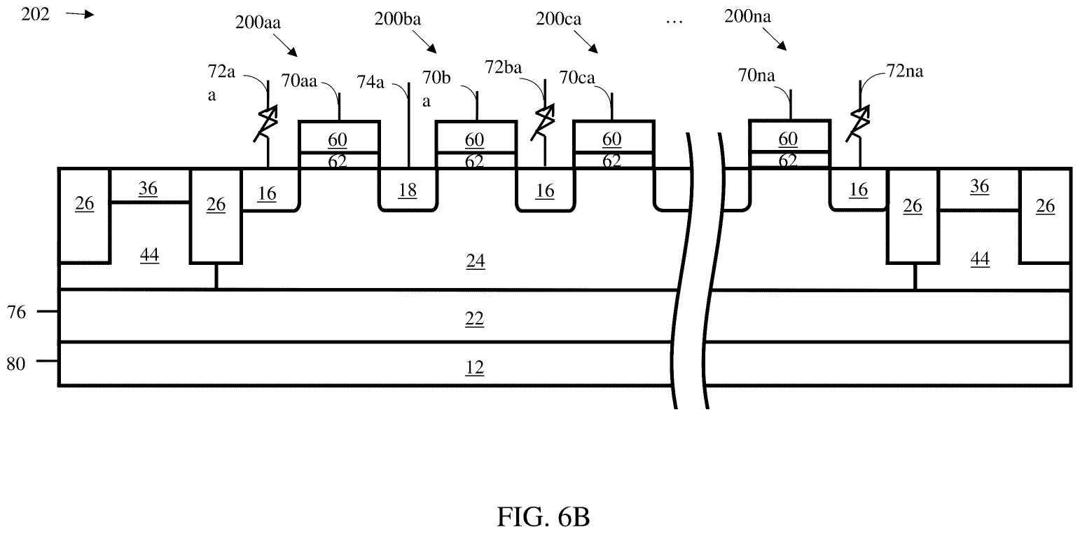

FIG. 6A shows a cross-sectional view of memory array 202 shown in FIG. 5 along the column direction, specifically along the BL terminal 74a. Memory cells 200aa, 200ba, 200ca, and 200na are shown in FIG. 6A.

FIG. 6B shows another cross-sectional view of memory array 202 along the column direction, which also shows buried layer contact region 36 and buried layer contact body 44, which are used to apply voltage and/or current bias to the buried layer 22. The buried contact region 36 and buried layer contact 44 are shown at the edges of the plurality of memory cells 200, but buried contact region 36 and buried layer contact 44 may also be used to segment the memory array 202.

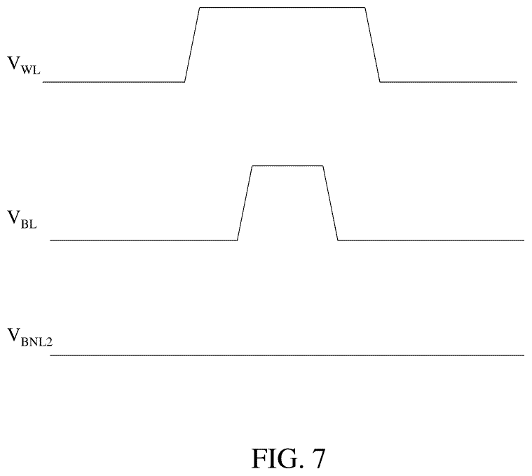

FIG. 7 illustrates an exemplary waveform that could be applied to a memory cell 200 during a write operation, according to an embodiment of the present invention. A positive VWL voltage is applied to the gate 60 through WL terminal 70, a positive VBL voltage is applied to the drain region 18 through BL terminal 74, and a high VBNL voltage (VBNL2) is applied to the buried layer 22 through BW terminal 76. As described above, this bias condition will result in higher drain 18 and source 16 currents, enhancing the write operation of memory cell 200.

A negative voltage may also be applied to the source region 16 through SL terminal 72. As described above, applying a negative voltage to the source region 16 may lower the positive voltage VBNL2 required to be applied to the buried layer 22 to result in higher source and drain current.

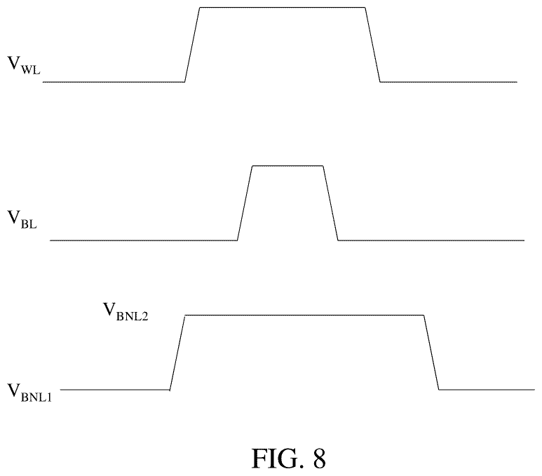

FIG. 8 illustrates another exemplary waveform that could be applied to memory cell 200 during a write operation according to an embodiment of the present invention. The voltage applied to the BW terminal 76 is initially kept at low VBNL voltage (VBNL1), and is only raised to the high VBNL voltage (VBNL2) during the write operation. As shown in FIG. 8, the BW terminal 76 is raised to VBNL2 in conjunction with the positive voltages applied to the WL terminal 70 (V_{WL}) and BL terminal 74 (V_{BL}). Similarly, a negative voltage may also be applied to the source region 16 through SL terminal 72.

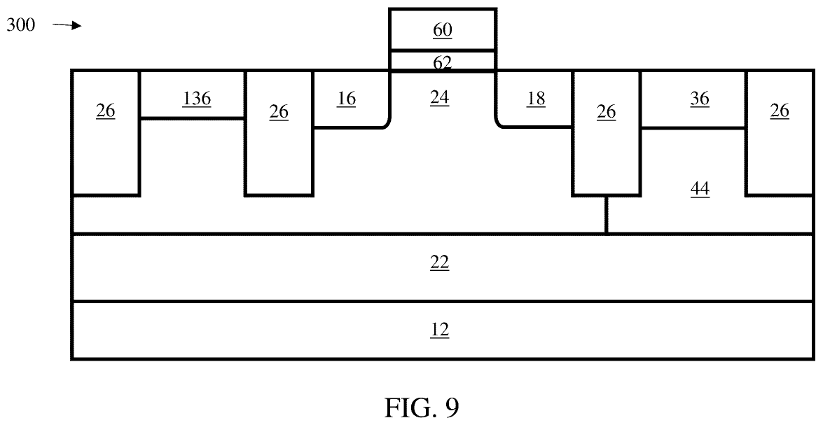

FIG. 9 illustrates a semiconductor device 300, according to an embodiment of the present invention, which includes a substrate 12 of a first conductivity type such as p-type, for example. Substrate 12 is typically made of silicon, but may also comprise, for example, germanium, silicon germanium, gallium arsenide, and/or other semiconductor materials. In some embodiments of the invention, substrate 12 can be the bulk material of the semiconductor wafer.

Semiconductor device 300 also includes a buried layer 22 of a second conductivity type, such as n-type, for example; a body 24 of the first conductivity type, such as p-type, for example; and source/drain regions 16 and 18 of the second conductivity type, such as n-type, for example. Buried layer 22 may be formed by an ion implantation process on the material of substrate 12. Alternatively, buried layer 22 can be grown epitaxially on top of substrate 12 or formed through a solid state diffusion process. Body 24 may be the portion of the original substrate 12 above buried layer 22 if buried layer 22 is implanted. Alternatively, body 24 may be epitaxially grown on top of the buried layer 22 through a solid state diffusion process.

A source 16 and drain 18 having a second conductivity type, such as n-type, for example, are provided in body 24, so as to bound a portion of the top of the body 24. Source 16 and drain 18 may be formed by an implantation process on the material making up substrate 12, according to any implantation process known and typically used in the art. Alternatively, a solid state diffusion or a selective epitaxial growth process could be used to form source 16 and drain 18.

A gate 60 is positioned in between the source 16 and the drain 18, above body 24. The gate 60 is insulated from the body 24 by an insulating layer 62. Insulating layer 62 may be made of silicon oxide and/or other dielectric materials, including high-K dielectric materials, such as, but not limited to, tantalum peroxide, titanium oxide, zirconium oxide, hafnium oxide, and/or aluminum oxide. The gate 60 may be made of, for example, polysilicon material or metal gate electrode, such as tungsten, tantalum, titanium and their nitrides.

Insulating layers 26 (like, for example, shallow trench isolation (STI)), may be made of silicon oxide, for example, though other insulating materials may be used. The bottom of insulating layer 26 may reside above the buried layer 22 allowing buried layer 22 to be continuous as shown in FIG. 9.

Semiconductor device 300 further comprises body contact 136 having a first conductivity type. Body contact region 136 is typically more highly doped compared to the body region 24 to lower the contact resistance. Body contact region 136 may be used to apply voltage and/or current bias to the body region 24.

Semiconductor device 300 also comprises buried layer contact region 36 and buried layer contact body 44, both having a second conductivity type. Buried layer contact region 36 is typically more highly doped compared to the buried layer contact body 44 to lower the contact resistance. Buried layer contact region 36 may be used to apply voltage and/or current bias to the buried layer 22.

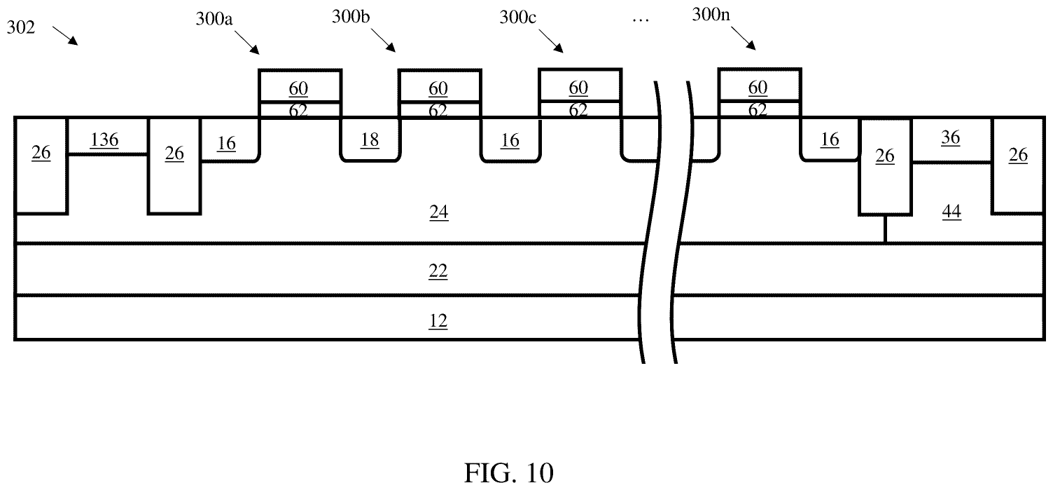

Body region 24 may be continuous over multiple semiconductor devices 300. FIG. 10 illustrates an array 302 having semiconductor devices 300a-300n having the same body region 24. Body contact region 136 and buried layer contact region 36 are used to apply voltage and/or current bias to the body region 24 and buried layer 22 in semiconductor devices 300a-300n, respectively.

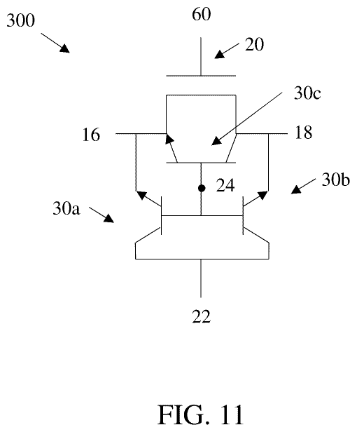

FIG. 11 illustrates an equivalent circuit representation of semiconductor device 300. Inherent in semiconductor device 300 are metal-oxide-semiconductor (MOS) transistor 20, formed by source 16, gate 60, drain 18, and body 24, and vertical BJTs 30a and 30b, formed by buried layer 22, body 24, and source 16 or drain 18, respectively. Also inherent in semiconductor device 300 is lateral BJT 30c, formed by source 16, body 24, and drain 18.

Applying a positive voltage or current bias to the body region 24 may be used to increase the current flow (from the drain region 18 to the source region 16) when semiconductor device 300 is in conducting mode. When semiconductor device 300 is in conducting mode, a positive voltage is applied to the gate region 60, a positive voltage is applied to the drain region 18, about zero voltage is applied to the source region 16, a positive voltage is applied to the body contact region 20, and zero or positive voltage is applied to the buried layer region 22.

The higher current flow is a result of a lower threshold voltage (Vt) when the body region 24 is positively biased (through the body contact region 136). The effect of the bias to the body region 24 is described by the following equation:

$${V}_{t} = {V}_{t 0} + ( γ \sqrt{\vert - 2 {∅}_{P} + {V}_{SB} \vert} - \sqrt{\vert 2 {∅}_{P} \vert} )$$

where: Vₜ is the threshold voltage when a body bias is present;
Vₜ₀ is the threshold voltage with zero bias applied;
γ is the body effect coefficient;
2ϕ_{P} is the surface potential; and
V_{SB} is the bias applied to the body region 24.

A positive bias applied to the body region 24 (through the body contact region 136) also turns on the intrinsic lateral bipolar transistor 30c, where the source region 16 functions as the emitter region, the body region 24 functions as the base region, and the drain region 18 functions as the collector region of the bipolar transistor 30c. The lateral bipolar transistor 30c also contributes to higher current flow (from the drain region 18 to the source region 16) when the body region 24 is positively biased.

A higher current flow to the source region 16 may also be achieved by utilizing the vertical bipolar transistor 30a. Additional current flow from the buried layer region 22 to the source region 16 may be obtained by applying a positive bias to the buried layer region 22 (through the buried layer contact region 36).

The current flow to the source region 16 is higher when positive bias is applied to the body region 24 compared to when about zero voltage is applied to the body region 24 as a result of the lower threshold voltage and the bipolar current flow.

In the exemplary bias condition above, zero voltage is applied to the source region 16, while positive bias is applied to the drain region 18 and buried layer region 22, resulting in a current flow direction into the source region 16. A zero voltage bias may be applied to the drain region 18, while positive bias is applied to the source region 16 and buried layer 22, resulting in a current flow into the drain region 18.

In another non-limiting embodiment, a negative voltage may be applied to the source region 16. As a result, a lower positive voltage can be applied to the buried layer region 22, while still maintaining the potential difference between the buried layer 22 (collector) and the source region 16 (emitter) that will result in increased on-state drain current.

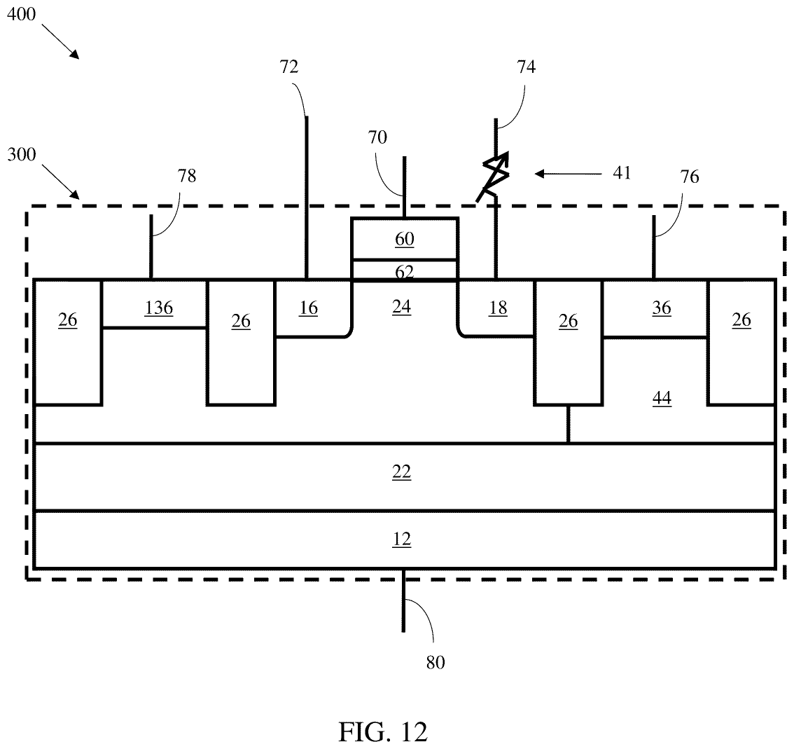

FIG. 12 illustrates a non-volatile memory cell 400, comprising a semiconductor device 300 functioning as a select device for a non-volatile memory element 41, according to an embodiment of the present invention. In this example, non-volatile memory element 41 is a resistive change element and is shown as a variable resistor. Resistive change element 41 may be formed from phase change memory material such as a chalcogenide or conductive bridging memory or metal oxide memory, and may take the form of metal-insulator-metal structure, in which transition metal oxide or perovskite metal oxide is used in conjunction with any reasonably good conductors, for example as described in “Overview of Phase-Change Chalcogenide Non-volatile Memory Technology”, S. Hudgens and b. Johnson, MRS Bulletin, vol. 29, issue 11, November 2004, p. 829-832, “Phase Change Memory”, Wong, H.-S. P. et al., Proceedings of the IEEE, vol. 98, no. 12, December 2010, pp. 2201-2227, “Nanoionics-based resistive switching memories”, R. Waser and M. Aono, Nature Materials, vol. 6, November 2007, pp. 833-840, and “Metal-Oxide RRAM”, Wong, H.-S. P. et. al., Proceedings of the IEEE, vol. 100, no. 6, June 2012, pp. 1951-1970, “Non-volatile RRAM embedded into 22FFL FinFET technology”, Golonzka, O. et al., 2019 Symposium on VLSI Technology, all of which are hereby incorporated herein, in their entireties, by reference thereto. Non-volatile memory element 41 may also comprise magnetoresistive change materials, ferroelectric, and/or ferromagnetic materials, for example as described in “MRAM as Embedded Non-Volatile Memory Solution for 22FFL FinFET Technology”, Golonzka, O. et al., 2018 IEEE International Electron Devices Meeting (IEDM), which is hereby incorporated herein, in its entirety, by reference thereto.

The resistive change element 41 is connected to the source or drain region 16 or 18 of the semiconductor device 300 having a buried layer 22, typically through a conductive element (for example via and metal used to form semiconductor circuits).

The semiconductor memory cell 400 further includes a word line (WL) terminal 70 electrically connected to gate 60, a source line (SL) terminal 72 electrically connected to source region 16, a bit line (BL) terminal 74 electrically connected to non-volatile memory element 41, which is subsequently connected to the drain region 18, a buried well (BW) terminal 76 electrically connected to buried layer region 22, a body terminal 78 connected to the body region 24, and a substrate terminal 80 electrically connected to substrate 12. Alternatively, the SL terminal 72 may be electrically connected to region 18 and BL terminal 74 may be electrically connected to non-volatile memory element 41 and subsequently to the source region 16.

The state of the memory cell 400 is determined by the resistivity of the resistive change element 41. The resistive change element 41 is written (from a low resistivity state to a high resistivity state and vice versa) by flowing an electrical current through the resistive change element 41. In the case of phase change materials, this involves the change of the crystallinity of the chalcogenide materials from crystalline state to amorphous state, while in metal oxide materials, this typically involves the annihilation of conductive filaments. As a result, it is typically desired to have a higher current flow through the semiconductor device 300 to enhance the write operation. The higher current flow can be achieved by applying a positive bias to the body region 24 and/or a positive bias to the buried layer region 22. The increased efficiency of the write operations may be used to increase the operating speed, or to lower the voltage applied for the write operations, reducing the operating power of the non-volatile memory cell 400.

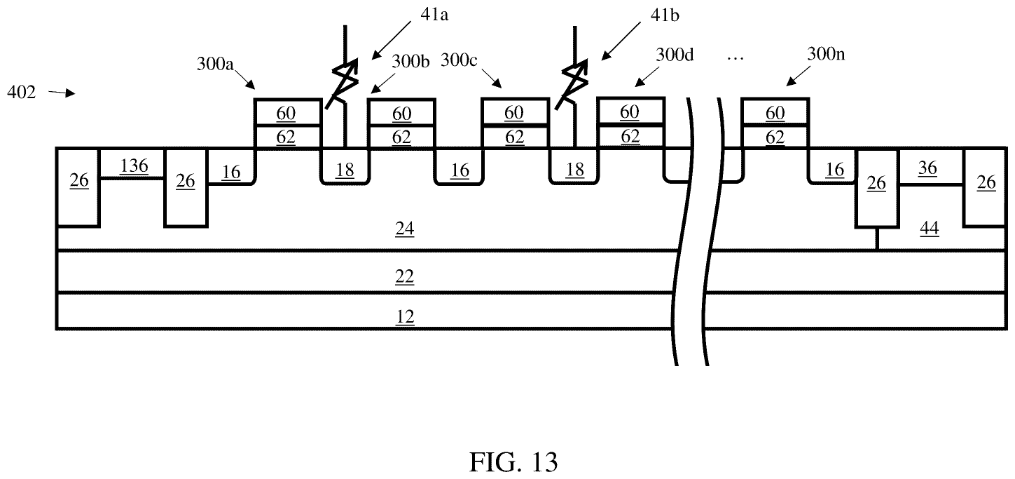

FIG. 13 shows a cross-sectional view of memory array 402, showing semiconductor devices 300a, 300b, 300c, 300d, and 300n, along with non-volatile memory elements 41a and 41b. In FIG. 13, non-volatile memory elements 41a and 41b are connected to the drain regions 18. However, the non-volatile memory elements 41a and 41b may alternatively be connected to the source regions 16. FIG. 13 also shows the buried layer contact region 36 and buried layer contact body 44, which are used to apply voltage and/or current bias to the buried layer 22, as well as the body contact region 136, which is used to apply voltage and/or current bias to the body region 24. Body region 24 may be continuous over multiple semiconductor devices 300.

From the foregoing it can be seen that semiconductor arrays and semiconductor memory cells having higher current flow have been described. While the foregoing written description of the invention enables one of ordinary skill to make and use what is considered presently to be the best mode thereof, those of ordinary skill will understand and appreciate the existence of variations, combinations, and equivalents of the specific embodiments, methods, and examples herein. The invention should therefore not be limited by the above described embodiments, methods, and examples, but by all embodiments and methods within the scope and spirit of the invention as claimed.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

That which is claimed is:

1. A method of increasing write current of a non-volatile memory cell, said method comprising:
providing a non-volatile memory cell comprising:
a semiconductor device comprising a substrate having a first conductivity type selected from p-type conductivity type and n-type conductivity type; a buried layer having a second conductivity type selected from said p-type conductivity type and said n-type conductivity type and being different from said first conductivity type; a body having said first conductivity type; a source region and a drain region each having said second conductivity type and being separated by the body; and a gate positioned in between the source region and the drain region; and
a non-volatile memory element connected to one of the source region and the drain region;
applying a positive voltage or current to the gate region;
applying a positive voltage or current to the drain region;
applying zero or a negative voltage or current to the source region;
applying zero or a positive voltage or current to the buried layer; and
applying a positive voltage or current to the body;
thereby increasing current flow from the drain region to the source region, thereby increasing write current of the non-volatile memory cell.

2. The method of claim 1, wherein said applying a positive voltage to the body lowers a threshold voltage of the semiconductor device.

3. The method of claim 1, wherein said applying a positive voltage or current to the body turns on an intrinsic lateral bipolar transistor formed by the source region, the body and the drain region.

4. The method of claim 3, wherein the intrinsic lateral bipolar transistor contributes to higher current flow from the drain region to the source region.

5. The method of claim 1, wherein said applying zero or a positive voltage to the buried layer comprises applying said positive voltage to the buried layer to provide additional current flow from the buried layer to the source region.

6. The method of claim 5, wherein said applying zero or a negative voltage or current to the source region comprises applying said negative voltage or current to the source region, so that said applying said positive voltage to the buried layer is a lower positive voltage than a positive voltage required to be applied to the buried layer to achieve increased on-state drain current when zero voltage or current is applied to the source region.

7. A non-volatile memory cell configured to function with increased on-state drain current while in write operation, said non-volatile memory cell comprising:
a substrate having a first conductivity type selected from p-type conductivity type and n-type conductivity type;
a buried layer having a second conductivity type selected from said p-type conductivity type and said n-type conductivity type and being different from said first conductivity type;
a body having said first conductivity type;
a source region and a drain region each having said second conductivity type and being separated by said body;
a gate positioned in between said source region and said drain region; and
a non-volatile memory element connected to one of said source region and said drain region,
wherein application of a positive voltage or current to said gate region, a positive voltage or current to said drain region, zero or a negative voltage or current to said source region, zero or a positive voltage or current to said buried layer, and a positive voltage or current to said body increases current flow from said drain region to said source region.

8. The semiconductor device of claim 7, wherein said application of a positive voltage or current to said body turns on an intrinsic lateral bipolar transistor formed by said source region, said body and said drain region.

9. The semiconductor device of claim 8, wherein said intrinsic lateral bipolar transistor contributes to higher current flow from said drain region to said source region.

10. The semiconductor device of claim 7, wherein said application of zero or a positive voltage to said buried layer comprises applying said positive voltage to said buried layer to provide additional current flow from said buried layer to said source region.

11. The semiconductor device of claim 10, wherein said application of zero or a negative voltage or current to said source region comprises applying said negative voltage or current to said source region, so that said application of said positive voltage to said buried layer is a lower positive voltage than a positive voltage required to be applied to said buried layer to achieve increased on-state drain current when zero voltage or current is applied to said source region.

12. The semiconductor device of claim 7, further comprising:
a body contact having said first conductivity type;
wherein said positive voltage or current to said body is applied through said body contact.

13. The semiconductor device of claim 12, wherein said body contact is more highly doped than said body.

14. The semiconductor device of claim 7, further comprising:
a buried layer contact region having said second conductivity type; and
a buried layer contact body having said second conductivity type and interconnecting said buried layer contact region and said buried layer;
wherein said application of zero or a positive voltage or current to said buried layer is applied through said buried layer contact region and said buried layer contact body.

15. The semiconductor device of claim 14, wherein said buried layer contact region is more highly doped than said buried layer contact body

16. A method of increasing write current of a non-volatile memory cell, said method comprising:
providing the non-volatile memory cell comprising:
a semiconductor device comprising a substrate having a first conductivity type selected from p-type conductivity type and n-type conductivity type; a buried layer having a second conductivity type selected from said p-type conductivity type and said n-type conductivity type and being different from said first conductivity type; a body having said first conductivity type; a source region and a drain region each having said second conductivity type and being separated by the body; and a gate positioned in between the source region and the drain region; and
a non-volatile memory element connected to one of the source region and the drain region;
applying a positive voltage or current to the gate region;
applying a positive voltage or current to the drain region;
applying zero or a negative voltage or current to the source region;
applying zero voltage or current to the substrate; and
applying a positive voltage or current to the buried layer;
wherein the positive voltage or current applied by said applying a positive voltage or current to the buried layer is sufficiently high to cause an ionization impact process forming a base current of an inherent lateral bipolar junction transistor (BJT);
wherein the positive voltage or current applied by said applying a positive voltage or current to the gate region and/or drain region is sufficiently high to elevate a potential of the body to a level to turn on an inherent vertical bipolar junction transistor (BJT);
wherein said on-state drain current of the semiconductor device is a sum of MOS transistor (formed by the source region, the gate region, the drain region and the body) current and current through the lateral BJT; and
wherein total current flow into the source region is a sum of the MOS transistor current, the current through the lateral BJT and current through the vertical BJT.

17. The method of claim 16, wherein an off-state current of the semiconductor device is the same as when voltage or current applied to the buried layer is zero.

18. The method of claim 16, wherein said applying a positive voltage or current to the buried layer comprises applying about three volts to the buried layer.

19. The method of claim 16, wherein said applying zero or a negative voltage or current to the source region comprises applying said negative voltage or current to the source region, so that said application of said positive voltage to the buried layer is a lower positive voltage than a positive voltage required to be applied to the buried layer to achieve increased on-state drain current when zero voltage or current is applied to the source region.

20. The method of claim 19, wherein said negative voltage or current applied to the source region is-0.2 V and said positive voltage applied to the buried layer is +2.8 V.
